(19) United States
(12) Patent Application Publication
(10) Pub. No.: US 2025/0351575 A1
(43) Pub. Date: Nov. 13, 2025

(54) ARRAY SUBSTRATE AND DISPLAY PANEL

(71) Applicant: HKC CORPORATION LIMITED, Shenzhen (CN)

(72) Inventors: Chuan Wu, Shenzhen (CN); Lidan Ye, Shenzhen (CN)

(21) Appl. No.: 19/201,992

(22) Filed: May 8, 2025

(30) Foreign Application Priority Data
May 10, 2024 (CN) 202410573673.X

(51) Int. Cl. H10D 86/40; H10D 86/60; H10D 89/60

(52) U.S. Cl. CPC H10D 86/443; H10D 86/60; H10D 89/611; H10D 89/921

(57) ABSTRACT

The array substrate includes a carrier substrate, a first signal line and an electrostatic protective circuit, the carrier substrate is provided with a display area and a non-display area; the first signal line is located in the non-display area; the electrostatic protective circuit includes a diode ring, the diode ring is located in the non-display area, the diode ring includes a gate pattern layer and a source and drain pattern layer, the source and drain pattern layer is located on the side of the gate pattern layer and the first signal line away from the carrier substrate, the source and drain pattern layer is connected to the first signal line through a first through hole, and the source and drain pattern layer is connected to the gate pattern layer through a second through hole.

### CROSS REFERENCE TO RELATED APPLICATION

Pursuant to 35 U.S.C. § 119 and the Paris Convention Treaty, the present application claims the benefit of Chinese Patent Application No. 202410573673.X filed May 10, 2024, the contents of which are incorporated herein by reference.

### TECHNICAL FIELD

The present application relates to the technical field of display panels, and more particularly to an array substrate and a display panel.

### BACKGROUND

The array substrate is an important structure in various display devices, such as a Thin Film Transistor-Liquid Crystal Display (TFT-LCD) and an Organic Light-Emitting Diode (OLED) display device.

The array substrate includes a carrier substrate and a circuit formed on a surface of the carrier substrate. The circuit structure on the surface of the array substrate is relatively fine, and the preparation process is relatively long. During the preparation process, some parts are prone to accumulate charges and eventually form electrostatic discharge, resulting in partial structure of the circuit being destroyed. For example, a signal line is usually distributed on the edge of the carrier substrate, one end of the signal line is connected to an electrostatic protective circuit, and the signal line and the electrostatic protective circuit are connected through a through hole. If a large amount of charge accumulates on the signal line, it is easy to form a discharge, burn or even burn the through hole connecting the signal line and the electrostatic protective circuit, which affects the connection between the signal line and the electrostatic protective circuit, and the yield of the array substrate is reduced.

### SUMMARY

The embodiment of the present application provides an array substrate and display panel, which can reduce the possibility of burning of the through holes connecting signal lines and electrostatic protective circuits due to electrostatic discharge, which is conducive to improving the yield of the array substrate.

The first aspect of the embodiment of the present application provides an array substrate, the array substrate includes:
a carrier substrate, provided with a display area and a non-display area;
a first signal line, located in the non-display area;
an electrostatic protective circuit, including a diode ring; wherein the diode ring is located in the non-display area, the diode ring includes a gate pattern layer and a source and drain pattern layer, the source and drain pattern layer is located on a side of the gate pattern layer and the first signal line away from the carrier substrate the source and drain pattern layer is connected to the first signal line through a first through hole, the source and drain pattern layer is connected to the gate pattern layer through a second through hole, and an area of the first through hole is larger than an area of the second through hole.

In some examples, the first through hole includes a plurality of sub-through holes, the plurality of sub-through holes connect the source and drain pattern layer and the first signal line, and a sum of areas of the plurality of sub-through holes is greater than the area of the second through hole.

In some examples, the gate pattern layer and the first signal line are arranged in a same layer.

In some examples, the gate pattern layer includes a first gate and a second gate, the first gate is connected to the first signal line, a gap is formed between the second gate and the first gate, and a gap is formed between the second gate and the first signal line;
the source and drain pattern layer includes a first source and drain layer and a second source and drain layer, the first source and drain layer partially overlaps with the first gate, the second gate, and the first signal line, respectively, and the second source and drain layer partially overlaps with the first gate and the second gate, respectively;
the first through hole is connected to the first source and drain layer and the first signal line; and
the second through hole is connected to the second source and drain layer and the second gate.

In some examples, the gate pattern layer further includes a third gate and a fourth gate, the third gate is connected to the second gate, a gap is formed between the fourth gate and the third gate, and a gap is formed between the fourth gate and the second gate; and
the source and drain pattern layer further includes a third source and drain layer, the third source and drain layer partially overlaps with the third gate and the fourth gate, respectively, the third source and drain layer is connected to the fourth gate through a third through hole, and an area of the third through hole is smaller than the area of the first through hole.

In some examples, the first signal line includes a first connection portion and a linear body, a width of the first connection portion is greater than a width of the linear body, the first connection portion partially overlaps with the first source and drain layer, and is connected to the first source and drain layer through the first through hole.

In some examples, the gate pattern layer further includes a second connection portion, the second connection portion is connected to the second gate, the second connection portion partially overlaps with the second source and drain layer, and is connected to the second source and drain layer through the second through hole.

In some examples, an area of the first connection portion is greater than an area of the second connection portion.

In some examples, the electrostatic protective circuit further includes a second signal line, and the second signal line is arranged in the same layer as the source and drain pattern layer and is connected to the source and drain pattern layer.

In a second aspect of an embodiment of the present application, a display panel is provided, which includes a pairing substrate and an array substrate as described in the first aspect, and the pairing substrate is arranged opposite to the array substrate.

The first aspect of the embodiment of the present application is to provide a first signal line and an electrostatic protective circuit on the carrier substrate, and the electrostatic protective circuit is connected to the first signal line. The electrostatic protective circuit is used to prevent static electricity from damaging the array substrate during the operation of the array substrate. The electrostatic protective circuit includes a diode ring, and the source and drain pattern layer of the diode ring is connected to the first signal line through a first through hole, and the source and drain pattern layer of the diode ring is connected to the gate pattern layer through a second through hole, so that in the process of preparing the source and drain pattern layer, the electrostatic charge accumulated in the first signal line will be released through the first through hole to the film layer for preparing the source and drain pattern layer. Since the area of the first through hole is larger than that of the second through hole, the electrostatic charge accumulated in the first signal line can be introduced into the film layer for preparing the source and drain pattern layer more quickly through the first through hole, the possibility of the first through hole being burned or destroyed by static electricity can be reduced, which is beneficial to improving the yield of the array substrate.

It can be understood that the beneficial effects of the second aspect mentioned above can be referred to the relevant description in the first aspect mentioned above, and which will not be repeated here.

### BRIEF DESCRIPTION OF THE DRAWINGS

In order to more clearly illustrate the technical solutions in the embodiments of the present application, the drawings required to be used in the embodiments or the prior art description will be briefly introduced below. Obviously, the drawings described below are only some embodiments of the present application. For ordinary technicians in this field, other drawings can be obtained based on these drawings without creative work.

FIG. 1 is a top view schematic diagram of an array substrate provided in an Embodiment 1 of the present application;

FIG. 2 is an equivalent circuit diagram of an electrostatic protective circuit provided in the embodiment of the present application;

FIG. 3 is a partially enlarged schematic diagram in FIG. 1;

FIG. 4 is an A-A cross-sectional view of FIG. 3;

FIG. 5 is a structural schematic diagram of an array substrate provided in Embodiment 2 of the present application;

FIG. 6 is a structural schematic diagram of a non-display area of an array substrate provided in Embodiment 2 of the present application;

FIG. 7 is an equivalent circuit diagram of an electrostatic protective circuit of an array substrate provided in Embodiment 3 of the present application;

FIG. 8 is a structural schematic diagram of an array substrate provided in Embodiment 3 of the present application; and

FIG. 9 is a structural schematic diagram of an array substrate provided in Embodiment 4 of the present application.

### REFERENCE NUMERALS

10—carrier substrate; 10a—display area; 10b—non-display area; 11—first signal line; 111—first connection portion; 112—linear body; 20—electrostatic protective circuit; 21—second signal line; 22—diode ring; 221—gate pattern layer; 222—source and drain pattern layer; 223—active pattern layer; 2211—first gate; 2212—second gate; 2213—third gate; 2214—fourth gate; 2215—second connection portion; 2231—first active layer; 2232—second active layer; 2233—third active layer; 2234—fourth active layer; 2221—first source and drain layer; 2222—second source and drain layer; 2223—third source and drain layer; 222a;-first electrode; 222b—second electrode; 31—first insulating layer; 32—second insulating layer; 33—third insulating layer; 34—fourth insulating layer; 31a—first through hole; 31b—second through hole; 31c—third through hole; 31d—sub-through hole; gate driver on array circuit: 40; and 41—bridging line.

### DESCRIPTION OF THE EMBODIMENTS

In the following description, for the purpose of explanation rather than limitation, specific details such as specific system structures and technologies are proposed to thoroughly understand the embodiments of the present application. However, it should be clear to those skilled in the art that the present application can also be implemented in other embodiments without these specific details. In other cases, detailed descriptions of well-known systems, devices, circuits, and methods are omitted to avoid unnecessary details that hinder the description of the present application.

It should also be understood that the term “and/or” used in the specification and appended claims refers to and includes any and all possible combinations of one or more of the associated listed items.

It should be noted that when an element is referred to as being “fixed to” or “set on” another element, it can be directly on the other element or indirectly on the other element. When an element is referred to as being “connected to” another element, it can be directly connected to the other element or indirectly connected to the other element.

It should be understood that the terms “length”, “width”, “upper”, “lower”, “front” “back”, “left”, “right”, “vertical”, “horizontal”, “top”, “bottom”, “inside”, “outside” and the like indicate the orientation or position relationship based on the orientation or position relationship shown in the drawings, which is only for the convenience of describing the present application and simplifying the description, and does not indicate or imply that the device or element referred to must have a specific orientation, be constructed and operated in a specific orientation, and therefore cannot be understood as a limitation on the present application.

In addition, in the description of the present application specification and the attached claims, the terms “first”, “second”, “third” and the like are only used to distinguish the description, and cannot be understood as indicating or implying relative importance.

The reference to “one embodiment” or “some embodiments” and the like described in the present application specification means that one or more embodiments of the present application include specific features, structures or characteristics described in conjunction with the embodiment. Therefore, the phrases “in one embodiment”, “in some embodiments”, “in other embodiments”, “in some other embodiments”, etc. that appear in different places in this specification do not necessarily refer to the same embodiment, but mean “one or more but not all embodiments”, unless otherwise specifically emphasized in other ways. The terms “include”, “comprise”, “have” and their variations all mean “including but not limited to”, unless otherwise specifically emphasized in other ways. “Multiple” refers to two or more.

### Embodiment 1

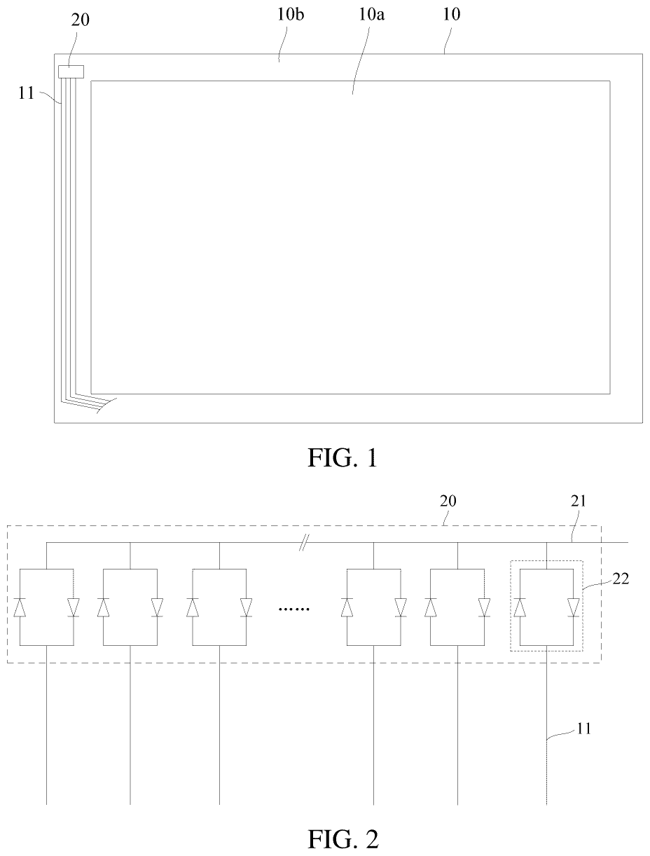

FIG. 1 is a top schematic diagram of an array substrate provided in Embodiment 1 of the present application. As shown in FIG. 1, the array substrate includes a carrier substrate 10 and a circuit formed on one side of the carrier substrate 10. The carrier substrate 10, as a carrier, is provided with a display area 10a and a non-display area 10b. The display area 10a is generally located in the middle of the carrier substrate 10, and the non-display area 10b is generally located at the edge of the carrier substrate 10. A first signal line 11 and an electrostatic protective circuit 20 are provided in the non-display area 10b of the carrier substrate 10, and one end of the first signal line 11 is connected to the electrostatic protective circuit 20.

FIG. 2 is an equivalent circuit diagram of the electrostatic protective circuit provided in the embodiment of the present application. As shown in FIG. 2, the electrostatic protective circuit 20 may include a second signal line 21 and a plurality of Diode Rings (DR) 22. The diode rings 22 are located in the non-display area 10b.

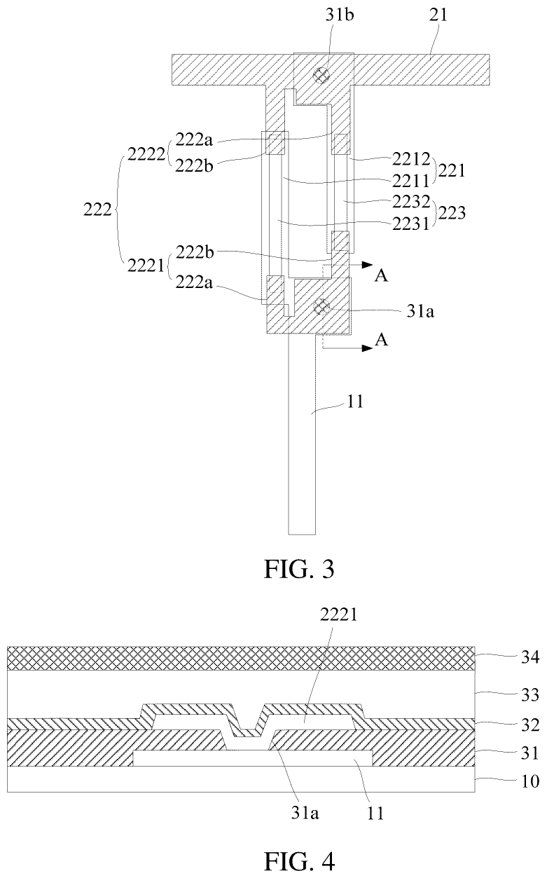

FIG. 3 is a partially enlarged schematic diagram in FIG. 1. As shown in FIG. 3, the diode ring 22 includes a gate pattern layer 221, a source and drain pattern layer 222, and an active pattern layer 223. The active pattern layer 223 and the source and drain pattern layer 222 are both located on the side of the gate pattern layer 221 away from the carrier substrate 10.

In the embodiment of the present application, the gate pattern layer 221, the active pattern layer 223, and the source and drain pattern layer 222 form two thin film transistors.

The gate pattern layer 221 includes a first gate 2211 and a second gate 2212.

The active pattern layer 223 includes a first active layer 2231 and a second active layer 2232, the first active layer 2231 is located on the side of the first gate 2211 away from the carrier substrate 10, and the first active layer 2231 overlaps at least partially with the first gate 2211. The second active layer 2232 is located on the side of the second gate 2212 away from the carrier substrate 10, and the second active layer 2232 at least partially overlaps with the second gate 2212.

In the embodiment of the present application, the overlap of two structures means that the orthographic projections of the two structures on the surface of the carrier substrate 10 overlap, that is, the orthographic projection of one structure on the surface of the carrier substrate 10 is at least partially located within the orthographic projection of the other structure on the surface of the carrier substrate 10. For example, the partial overlap of the second active layer 2232 and the second gate 2212 here means that the orthographic projection of the second active layer 2232 on the surface of the carrier substrate 10 overlaps with the orthographic projection of the second gate 2212 on the surface of the carrier substrate 10, that is, the orthographic projection of the second active layer 2232 on the surface of the carrier substrate 10 is at least partially located within the orthographic projection of the second gate 2212 on the surface of the carrier substrate 10.

The source and drain pattern layer 222 includes a first source and drain layer 2221 and a second source and drain layer 2222. The first source and drain layer 2221 includes a first electrode 222a and a second electrode 222b, and the second source and drain layer 2222 also includes a first electrode 222a and a second electrode 222b. The first electrode 222a is one of the source and the drain, and the second electrode 222b is the other of the source and the drain.

The first gate 2211 is connected to the first signal line 11, a gap is formed between the second gate 2212 and the first gate 2211, and a gap is formed between the second gate 2212 and the first signal line 11.

The first source and drain layer 2221 partially overlaps with the first gate 2211 and the second gate 2212, respectively. The first electrode 222a of the first source and drain layer 2221 partially overlaps with the first gate 2211 and partially overlaps with the first active layer 2231; and the second electrode 222b of the first source and drain layer 2221 partially overlaps with the second gate 2212 and partially overlaps with the second active layer 2232.

The second source and drain layer 2222 partially overlaps with the first gate 2211 and the second gate 2212, respectively. The first electrode 222a of the second source and drain layer 2222 partially overlaps with the second gate 2212 and partially overlaps with the second active layer 2232; and the second electrode 222b of the second source and drain layer 2222 partially overlaps with the first gate 2211 and partially overlaps with the first active layer 2231.

FIG. 4 is an A-A cross-sectional view of FIG. 3. As shown in FIG. 4, the array substrate further includes a first insulating layer 31, which is located on the side of the first signal line 11 away from the carrier substrate 10. The first insulating layer 31 has a first through hole 31a exposing the first signal line 11. The first signal line 11 is connected to the first source and drain layer 2221 through the first through hole 31a.

In the embodiment of the present application, unless otherwise specified, being connected through a through hole refers to achieving electrical connection, which is achieved by a structure located in the through hole. The structure used to achieve electrical connection in the through hole may be a part of any one of the two structures at both ends of the through hole, or may be other structures other than the two structures at both ends of the through hole. For example, the first signal line 11 is connected to the first source and drain layer 2221 through the first through hole 31a, which means that the first signal line 11 and the first source and drain layer 2221 are electrically connected, and the structure used to achieve electrical connection between the first signal line 11 and the first source and drain layer 2221 in the first through hole 31a is the part of the first source and drain layer 2221 located in the first through hole 31a.

The first insulating layer 31 is also provided with a second through hole 31b, and the second source and drain layer 2222 is connected to the second gate 2212 through the second through hole 31b.

The first through hole 31a and the second through hole 31b are of the same size, that is, they have the same area. This is because, in the process of designing the through hole, the lower limit of the size of the through hole is usually determined according to the depth of the through hole. When the depth of the through hole is fixed, the smaller the through hole is designed, the easier it is for the film layer in the through hole to break. The first through hole 31a and the second through hole 31b are usually prepared by the same patterning process, the depths of the through holes are the same, and the functions are also the same, both connecting different film layers to form an electrical connection between the film layers arranged in different layers. Therefore, when preparing the array substrate, the first through hole 31a and the second through hole 31b are usually designed to be the same size by the those skilled in the art, as long as the etched first through hole 31a and the second through hole 31b can form an electrical connection between the film layers arranged in different layers.

The length of the first signal line 11 is generally longer. The longer the length, the easier it is to accumulate charge in the process of preparing the array substrate. This results in electrostatic discharge being formed at the first through hole 31a during the preparation of a structure connected to the first signal line 11 through a through hole, for example, during the preparation of the first source and drain layer 2221, and the first through hole 31a may be burned or even destroyed by static electricity. The intuitive manifestation is that the first through hole 31a of the array substrate turns black, and the array substrate functions abnormally, which directly affects the yield of the array substrate. If the etching at the first through hole 31a is uneven, the morphology of the first through hole 31a is irregular, or there are burrs or foreign matter remaining, the risk caused by electrostatic discharge will be further increased.

### Embodiment 2

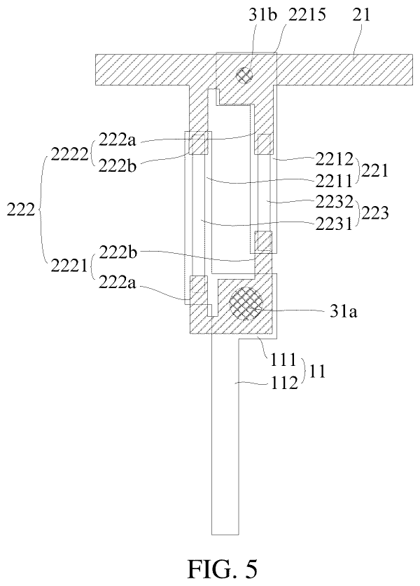

FIG. 5 is a structural schematic diagram of an array substrate provided in Embodiment 2 of the present application. Compared with the example shown in FIG. 3, in the array substrate shown in FIG. 5, the area of the first through hole 31a is larger than the area of the second through hole 31b. The cross-sectional structure of the array substrate shown in FIG. 5 at the first through hole 31a can refer to FIG. 4.

In the embodiment of the present application, the area of the through hole refers to the area of the orthographic projection of the through hole on the carrier substrate 10, or it may refer to the area of one end of the through hole close to the carrier substrate 10.

By providing the first signal line 11 and the electrostatic protective circuit 20 on the carrier substrate 10, the electrostatic protective circuit 20 is connected to the first signal line 11, and the electrostatic protective circuit 20 is used to prevent static electricity from damaging the array substrate during the operation of the array substrate. The electrostatic protective circuit 20 includes a diode ring 22, and the source and drain pattern layer 222 of the diode ring 22 is connected to the first signal line 11 through the first through hole 31a, and is connected to the gate pattern layer 221 through the second through hole 31b, so that in the process of preparing the source and drain pattern layer 222, the electrostatic charge accumulated in the first signal line 11 can be released through the first through hole 31a to the film layer for preparing the source and drain pattern layer 222.

In the process of preparing the array substrate, since the length of the first signal line 11 is longer, the first signal line 11 is easy to accumulate more electrostatic charge. The second gate 2212 may also accumulate a certain amount of electrostatic charge, but the length of the second gate 2212 is much shorter than that of the first signal line 11, and the accumulated electrostatic charge is much less. In the embodiment of the present application, the area of the first through hole 31a is larger than the area of the second through hole 31b. Under the condition that the first through hole 31a enables the source and drain pattern layer 222 to form an electrical connection with the first signal line 11, the larger first through hole 31a can allow the electrostatic charge accumulated in the first signal line 11 to be introduced into the film layer for preparing the source and drain pattern layer 222 more quickly through the first through hole 31a, thereby the possibility of the first through hole 31a being burned or burned by static electricity is reduced, which is beneficial to improving the yield of the array substrate. The electrostatic charge accumulated by the second gate 2212 is much less than that of the first signal line 11, and discharge is generated at the second through hole 31b, and the risk of burning the second through hole 31b is very low, so the area of the second through hole 31b is arranged smaller than that of the first through hole 31a.

In the embodiment of the present application, the gate pattern layer 221 and the first signal line 11 are arranged in the same layer.

Since the gate pattern layer 221 and the first signal line 11 are arranged in the same layer, the gate pattern layer 221 and the first signal line 11 can be formed by the same patterning process to achieve the purpose of saving process.

As shown in FIG. 5, the first signal line 11 includes a first connection portion 111 and a linear body 112. The width of the first connection portion 111 is greater than the width of the linear body 112. The first connection portion 111 partially overlaps with the first source and drain layer 2221 and is connected to the first source and drain layer 2221 through the first through hole 31a.

In the embodiment of the present application, the width of the linear body 112 refers to the distance between the two opposite sides of the linear body 112 in a direction parallel to the carrier substrate 10 and perpendicular to the linear body 112. The width of the first connection portion 111 refers to the distance between the two opposite sides of the first connection portion 111 in a direction parallel to the carrier substrate 10 and perpendicular to the linear body 112.

The linear body 112 is arranged thinner, which is conducive to reducing the space occupied by the first signal line 11 and facilitating wiring. The first connection portion 111 is arranged wider, which can facilitate the providing of the first through hole 31a with a larger area.

As an example, the first gate 2211 can be connected to the first connection portion 111 to form an integrated structure.

As shown in FIG. 5, the gate pattern layer 221 also includes a second connection portion 2215. The second connection portion 2215 is connected to the second gate 2212, and the second connection portion 2215 partially overlaps with the second source and drain layer 2222 and is connected through the second through hole 31b.

The second connection portion 2215 provides a portion with relatively large area to facilitate the connection between the gate pattern layer 221 and the second source and drain layer 2222 through the second through hole 31b.

As an example, the area of the first connection portion 111 is greater than the area of the second connection portion 2215.

In the embodiment of the present application, the area of the first connection portion 111 refers to the area of the orthographic projection of the first connection portion 111 on the carrier substrate 10; the area of the second connection portion 2215 refers to the area of the orthographic projection of the second connection portion 2215 on the carrier substrate 10. The area of the first connection portion 111 is arranged larger to facilitate the providing of a first through hole 31a with a larger area.

As shown in FIG. 5, the electrostatic protective circuit also includes a second signal line 21, which is arranged in the same layer as the source and drain pattern layer 222 and is connected to the source and drain pattern layer 222.

In the embodiment of the present application, the second signal line 21 is connected to the second source and drain layer 2222.

The second signal line 21 is used to release static electricity. Exemplarily, the second signal line 21 can be a common signal line, that is, the common signal line is reused to release static electricity. In other possible implementations, the second signal line 21 can also be a signal line other than the common signal line.

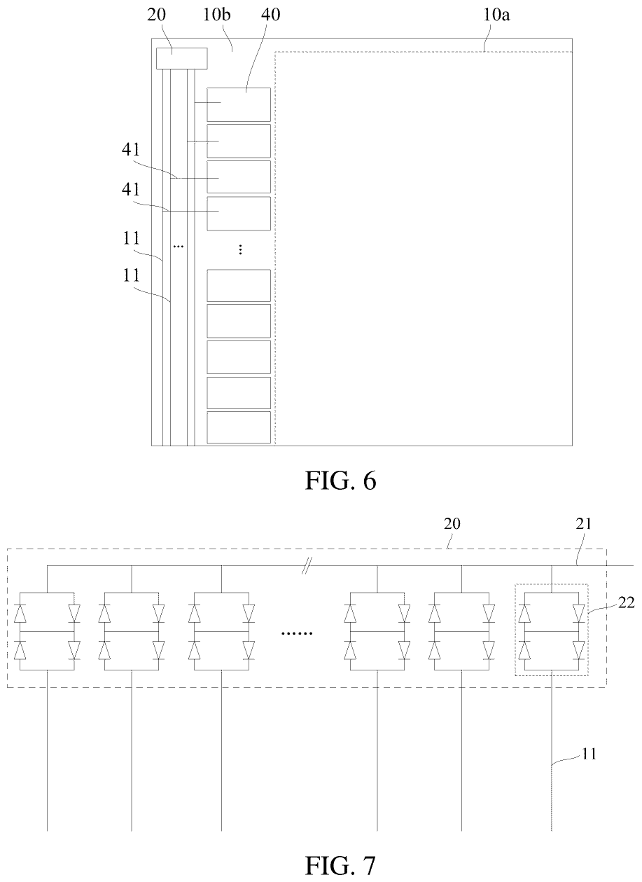

FIG. 6 is a structural schematic diagram of a non-display area of an array substrate provided in Embodiment 2 of the present application. As shown in FIG. 6, the array substrate also includes a bridging line 41 and a plurality of gate driver on array circuits 40. The plurality of gate driver on array circuits 40 are located between the first signal line 11 and the display area 10a, and the plurality of gate driver on array circuits 40 are arranged in sequence along the length direction of the first signal line 11.

The circuit on the surface of the carrier substrate 10 generally includes a pixel circuit located in the display area 10a and a drive circuit located in the non-display area 10b. The drive circuit of the non-display area 10b, for example, may include a Gate Driver On Array (GOA) circuit, and the gate driver on array circuit may include a gate driver on array circuit and a busline, the gate driver on array circuit is connected to the pixel circuit located in the display area 10a, and the busline may include a Clock signal line. As an example, in the embodiment of the present application, the first signal line 11 may be a clock signal line.

The bridging line 41 may be arranged in the same layer as the source and drain pattern layer 222, and the first signal line 11 is connected to the gate driver on array circuit 40 through the bridging line 41. Since the bridging line 41 and the source and drain pattern layer 222 are arranged in the same layer, the bridging line 41 and the source and drain pattern layer 222 can be formed by the same patterning process to achieve the purpose of saving process.

Exemplarily, the first signal line 11 may be a single-layer structure made of a metal material, such as a single-layer structure formed by metal copper Cu, or a multi-layer structure made of a metal material, such as Al/Mo/MTD material, that is, a multi-layer structure of an aluminum layer, a molybdenum layer, and a molybdenum nickel titanium alloy layer.

The first insulating layer 31 may be located in the display area 10a and the non-display area 10b. Exemplarily, the first insulating layer 31 may be a gate insulating layer. The first insulating layer 31 may be made of an inorganic non-metallic material, for example, the first insulating layer 31 may include at least one of a silicon nitride layer and a silicon oxide layer. Exemplarily, the first insulating layer 31 includes a SiNₓ layer and a SiOₓ layer laminated on the side of the SiNₓ layer away from the carrier substrate 10.

Exemplarily, the thin film transistor in the electrostatic protective circuit 20 may be an oxide thin film transistor, and the first active layer 2231 and the second active layer 2232 may be a metal oxide semiconductor layer. In some examples, the thin film transistor may also be a polycrystalline silicon thin film transistor, an amorphous silicon thin film transistor, or other thin film transistors.

As shown in FIG. 4, the array substrate further includes a second insulating layer 32, a third insulating layer 33, and a fourth insulating layer 34. The second insulating layer 32 covers the side of the source and drain pattern layer 222 away from the carrier substrate 10, the third insulating layer 33 is located on the side of the second insulating layer 32 away from the carrier substrate 10, and the fourth insulating layer 34 is located on the side of the third insulating layer 33 away from the carrier substrate 10.

The second insulating layer 32 can be located in the display area 10a and the non-display area 10b of the carrier substrate 10. Exemplarily, the second insulating layer 32 can be a passivationlayer (PVX), and the second insulating layer 32 can be made of an inorganic non-metallic material. For example, the second insulating layer 32 can include at least one of a silicon nitride layer and a silicon oxide layer. Exemplarily, the second insulating layer 32 includes a SiOₓ layer and a SiNₓ layer laminated on the side of the SiOₓ layer away from the carrier substrate 10.

The third insulating layer 33 can be made of an inorganic non-metallic material. For example, the third insulating layer 33 can be a resin layer, a photoresist layer, or an acrylic layer. Exemplarily, the third insulating layer 33 can be a perfluoroalkoxy resin PFA.

Optionally, the thickness of the third insulating layer 33 is 1.5 μm-3 μm. The thickness of the third insulating layer 33 is arranged relatively thick to form a relatively flat surface, so that the film layer formed subsequently is relatively flat.

In the display area 10a, the array substrate may also include a common electrode, which is located between the third insulating layer 33 and the fourth insulating layer 34.

Exemplarily, the common electrode can be made of ITO (Indium tin oxide) material. The fourth insulating layer 34 can be made of SiNₓ material.

### Embodiment 3

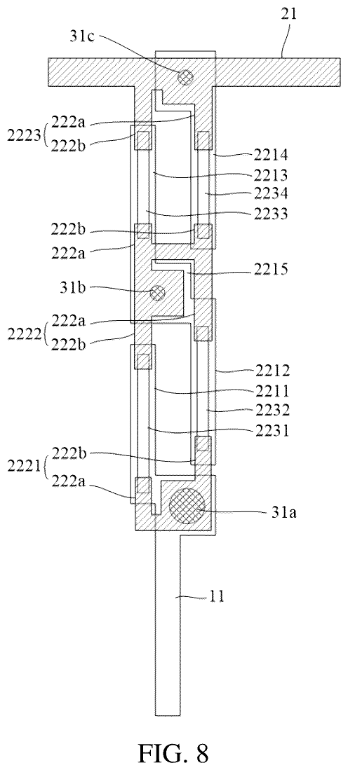

FIG. 7 is equivalent circuit diagram of an electrostatic protective circuit of an array substrate provided in Embodiment 3 of the present application. As shown in FIG. 7, in the electrostatic protective circuit, the diode ring 22 includes four thin film transistors. FIG. 8 is a structural schematic diagram of an array substrate provided in Embodiment 3 of the present application. Compared with the example shown in FIG. 5, in the array substrate shown in FIG. 8, the gate pattern layer 221, the active pattern layer 223 and the source and drain pattern layer 222 form four thin film transistors.

As shown in FIG. 8, in the array substrate, the gate pattern layer 221 further includes a third gate 2213 and a fourth gate 2214. The third gate 2213 is connected to the second gate 2212, a gap is formed between the fourth gate 2214 and the third gate 2213, and a gap is formed between the fourth gate 2214 and the second gate 2212.

The active pattern layer 223 further includes a third active layer 2233 and a fourth active layer 2234, the third active layer 2233 is located on the side of the third gate 2213 away from the carrier substrate 10, and the third active layer 2233 overlaps at least partially with the third gate 2213. The fourth active layer 2234 is located on the side of the fourth gate 2214 away from the carrier substrate 10, and the fourth active layer 2234 overlaps at least partially with the fourth gate 2214.

The second source and drain layer 2222 partially overlaps with the first gate 2211, the second gate 2212, the third gate 2213, and the fourth gate 2214, respectively. The second source and drain layer 2222 includes two first electrodes 222a and two second electrodes 222b. Among them, one first electrode 222a partially overlaps with the second gate 2212 and partially overlaps with the second active layer 2232; another first electrode 222a partially overlaps with the third gate 2213 and partially overlaps with the third active layer 2233; one second electrode 222b partially overlaps with the first gate 2211 and partially overlaps with the first active layer 2231; and another second electrode 222b partially overlaps with the fourth gate 2214 and partially overlaps with the fourth active layer 2234.

The source and drain pattern layer 222 also includes a third source and drain layer 2223. Among them, the third source and drain layer 2223 includes one first electrode 222a and one second electrode 222b.

The third source and drain layer 2223 partially overlaps with the third gate 2213 and the fourth gate 2214 respectively. The first electrode 222a of the third source and drain layer 2223 partially overlaps with the fourth gate 2214 and partially overlaps with the fourth active layer 2234; the second electrode 222b of the third source and drain layer 2223 partially overlaps with the third gate 2213 and partially overlaps with the third active layer 2233.

In the embodiment of the present application, the third source and drain layer 2223 is connected to the fourth gate 2214 through the third through hole 31c. The area of the third through hole 31c is smaller than that of the first through hole 31a.

In the embodiment of the present application, the electrostatic protective circuit 20 includes more thin film transistors, the circuit structure is more complex, and the electrostatic protective effect during the operation of the array substrate is better. In the process of preparing the array substrate, the electrostatic charge accumulated by the fourth gate 2214 is much less than that of the first signal line 11, and discharge is generated at the third through hole 31c. The risk of burning the third through hole 31c is very low, so the area of the third through hole 31c is arranged smaller than that of the first through hole 31a.

The specific structure of the electrostatic protective circuit 20 can have various forms. As an example, the embodiment of the present application provides an electrostatic protective circuit 20 with four thin film transistors. In other examples, the number of thin film transistors in the electrostatic protective circuit 20 can also be three, five, and six, etc.

### Embodiment 4

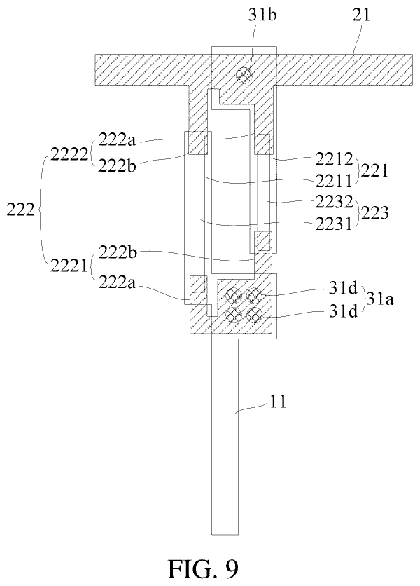

FIG. 9 is a structural schematic diagram of an array substrate provided in Embodiment 4 of the present application. Compared with the example shown in FIG. 5, in the array substrate shown in FIG. 9, the first through hole 31a includes a plurality of sub-through holes 31d, the sub-through holes 31d connect the source and drain pattern layer 222 and the first signal line 11, and the sum of the areas of the plurality of sub-through holes 31d is greater than the area of the second through hole 31b.

In this example, by providing the plurality of sub-through holes 31d, each sub-through hole 31d individually connects the source and drain pattern layer 222 to the first signal line 11, and each sub-through hole 31d is equivalent to a separate channel for releasing electrostatic charge. The sum of the areas of the sub-through holes 31d is greater than the area of the second through hole 31b, and the plurality of sub-through holes 31d release electrostatic charge together, and the possibility of a single sub-through hole 31d being damaged by static electricity burning is reduced.

### Embodiment 5

Embodiment 5 of the present application provides a display panel, which may be, but is not limited to, a display panel in a mobile phone, a tablet computer, a laptop computer, a display, a smart wearable device, or a vehicle-mounted display device. The display panel includes a pairing substrate and an array substrate, and the array substrate may be any of the array substrates shown in the aforementioned embodiments.

### Embodiment 6

Embodiment 6 of the present application provides a display device, which includes the display panel of the aforementioned embodiment. The display device may be, but is not limited to, a mobile phone, a tablet computer, a laptop computer, a display, a smart wearable device, and a vehicle-mounted display device.

The above embodiments are only used to illustrate the technical solution of the present application, but not to limit it. Although the present application is described in detail with reference to the aforementioned embodiments, ordinary technicians in the field should understand that they can still modify the technical solutions recorded in the aforementioned embodiments, or replace some of the technical features therein by equivalents. These modifications or replacements do not make the essence of the corresponding technical solutions deviate from the spirit and scope of the technical solutions of the embodiments of the present application, and should be included in the protection scope of the present application.

What is claimed is:

1. An array substrate, comprising:
a carrier substrate, provided with a display area and a non-display area;
a first signal line, located in the non-display area;
an electrostatic protective circuit, comprising a diode ring; wherein the diode ring is located in the non-display area, the diode ring comprises a gate pattern layer and a source and drain pattern layer, the source and drain pattern layer is located on a side of the gate pattern layer and the first signal line away from the carrier substrate, the source and drain pattern layer is connected to the first signal line through a first through hole, the source and drain pattern layer is connected to the gate pattern layer through a second through hole, and an area of the first through hole is larger than an area of the second through hole.

2. The array substrate according to claim 1, wherein the first through hole comprises a plurality of sub-through holes, the plurality of sub-through holes connect the source and drain pattern layer and the first signal line, and a sum of areas of the plurality of sub-through holes is greater than the area of the second through hole.

3. The array substrate according to claim 1, wherein the gate pattern layer and the first signal line are arranged in a same layer.

4. The array substrate according to claim 2, wherein the gate pattern layer and the first signal line are arranged in a same layer.

5. The array substrate according to claim 3, wherein the gate pattern layer comprises a first gate and a second gate, the first gate is connected to the first signal line, a gap is formed between the second gate and the first gate, and a gap is formed between the second gate and the first signal line;
the source and drain pattern layer comprises a first source and drain layer and a second source and drain layer, the first source and drain layer partially overlaps with the first gate, the second gate, and the first signal line, respectively, and the second source and drain layer partially overlaps with the first gate and the second gate, respectively;
the first through hole is connected to the first source and drain layer and the first signal line; and
the second through hole is connected to the second source and drain layer and the second gate.

6. The array substrate according to claim 5, wherein the gate pattern layer further comprises a third gate and a fourth gate, the third gate is connected to the second gate, a gap is formed between the fourth gate and the third gate, and a gap is formed between the fourth gate and the second gate; and
the source and drain pattern layer further comprises a third source and drain layer, the third source and drain layer partially overlaps with the third gate and the fourth gate, respectively, the third source and drain layer is connected to the fourth gate through a third through hole, and an area of the third through hole is smaller than the area of the first through hole.

7. The array substrate according to claim 5, wherein the first signal line comprises a first connection portion and a linear body, a width of the first connection portion is greater than a width of the linear body, the first connection portion partially overlaps with the first source and drain layer, and is connected to the first source and drain layer through the first through hole.

8. The array substrate according to claim 6, wherein the first signal line comprises a first connection portion and a linear body, a width of the first connection portion is greater than a width of the linear body, the first connection portion partially overlaps with the first source and drain layer, and is connected to the first source and drain layer through the first through hole.

9. The array substrate according to claim 7, wherein the gate pattern layer further comprises a second connection portion, the second connection portion is connected to the second gate, the second connection portion partially overlaps with the second source and drain layer, and is connected to the second source and drain layer through the second through hole.

10. The array substrate according to claim 9, wherein an area of the first connection portion is greater than an area of the second connection portion.

11. The array substrate according to claim 1, wherein the electrostatic protective circuit further comprises a second signal line, and the second signal line is arranged in the same layer as the source and drain pattern layer and is connected to the source and drain pattern layer.

12. A display panel, comprising an array substrate; wherein the array substrate comprises: a carrier substrate, provided with a display area and a non-display area;
a first signal line, located in the non-display area;
an electrostatic protective circuit, comprising a diode ring; wherein the diode ring is located in the non-display area, the diode ring comprises a gate pattern layer and a source and drain pattern layer, the source and drain pattern layer is located on a side of the gate pattern layer and the first signal line away from the carrier substrate, the source and drain pattern layer is connected to the first signal line through a first through hole, the source and drain pattern layer is connected to the gate pattern layer through a second through hole, and an area of the first through hole is larger than an area of the second through hole.

13. The display panel according to claim 12, wherein the first through hole comprises a plurality of sub-through holes, the plurality of sub-through holes connect the source and drain pattern layer and the first signal line, and a sum of areas of the plurality of sub-through holes is greater than the area of the second through hole.

14. The display panel according to claim 12, wherein the gate pattern layer and the first signal line are arranged in a same layer.

15. The display panel according to claim 14, wherein the gate pattern layer comprises a first gate and a second gate, the first gate is connected to the first signal line, a gap is formed between the second gate and the first gate, and a gap is formed between the second gate and the first signal line;
the source and drain pattern layer comprises a first source and drain layer and a second source and drain layer, the first source and drain layer partially overlaps with the first gate, the second gate, and the first signal line, respectively, and the second source and drain layer partially overlaps with the first gate and the second gate, respectively;
the first through hole is connected to the first source and drain layer and the first signal line; and
the second through hole is connected to the second source and drain layer and the second gate.

16. The display panel according to claim 15, wherein the gate pattern layer further comprises a third gate and a fourth gate, the third gate is connected to the second gate, a gap is formed between the fourth gate and the third gate, and a gap is formed between the fourth gate and the second gate; and
the source and drain pattern layer further comprises a third source and drain layer, the third source and drain layer partially overlaps with the third gate and the fourth gate, respectively, the third source and drain layer is connected to the fourth gate through a third through hole, and an area of the third through hole is smaller than the area of the first through hole.

17. The display panel according to claim 15, wherein the first signal line comprises a first connection portion and a linear body, a width of the first connection portion is greater than a width of the linear body, the first connection portion partially overlaps with the first source and drain layer, and is connected to the first source and drain layer through the first through hole.

18. The display panel according to claim 17, wherein the gate pattern layer further comprises a second connection portion, the second connection portion is connected to the second gate, the second connection portion partially overlaps with the second source and drain layer, and is connected to the second source and drain layer through the second through hole.

19. The display panel according to claim 18, wherein an area of the first connection portion is greater than an area of the second connection portion.

20. The display panel according to claim 12, wherein the electrostatic protective circuit further comprises a second signal line, and the second signal line is arranged in the same layer as the source and drain pattern layer and is connected to the source and drain pattern layer.
